(19) United States
(12) Patent Application Publication
(10) Pub. No.: US 2013/0140951 A1
(43) Pub. Date: Jun. 6, 2013

(54) PIEZOELECTRIC MOTOR, DRIVE UNIT, ROBOT HAND, ROBOT, ELECTRONIC COMPONENT TRANSPORTING APPARATUS, ELECTRONIC COMPONENT INSPECTING APPARATUS, AND PRINTER

(71) Applicant: Seiko Epson Corporation, Tokyo (JP)

(72) Inventors: Koichi KAMIJO, Matsumoto (JP); Osamu MIYAZAWA, Shimosuwa (JP)

(73) Assignee: SEIKO EPSON CORPORATION, Tokyo (JP)

(21) Appl. No.: 13/692,108

(22) Filed: Dec. 3, 2012

(30) Foreign Application Priority Data
Dec. 6, 2011 (JP) 2011-267225

(51) Int. Cl. H02N 2/12; B25J 15/00; B66C 1/10; B25J 15/02; H01L 41/053; H01L 41/09

(52) U.S. Cl. CPC H02N 2/12; H01L 41/053; H01L 41/0926; B66C 1/10; B25J 15/02; B25J 15/0009; Y10S 901/23
USPC 310/323.16; 310/348; 310/330; 74/490.03; 414/729; 294/213; 901/23

(57) ABSTRACT

A piezoelectric motor includes a piezoelectric element, a first support member, a second support member, a third support member, and a fourth support member that support the piezoelectric element, a elastic portion that presses the first support member and the second support member, a case that comes in contact with the third support member and the fourth support member, and a pressing plate that presses the elastic portion.

### BACKGROUND

1. Technical Field

The present invention relates to a piezoelectric motor and a drive unit, a robot, an electronic component transporting apparatus, an electronic component inspecting apparatus, and a printer using the piezoelectric motor.

2. Related Art

In the past, a piezoelectric motor (piezoelectric actuator) was known which causes a driven object to move rotationally or linearly using in-plane vibration of a piezoelectric element of a flat plate shape. As an example of such a piezoelectric motor, a structure was disclosed in which a position of a side surface corresponding to anode of vibration of a piezoelectric element is impelled and supported in a predetermined direction by an elastic member (for example, see JP-A-8-237971). As another example, a structure was disclosed in which support members supporting a piezoelectric element are disposed on four side surfaces perpendicular to the surface on which a feed electrode of a rectangular parallelepiped shape is formed and a compressing force is applied to the piezoelectric element via the support members by an elastic member so as to support the piezoelectric element (for example, see WO2007/080851). A structure of a piezoelectric motor was also disclosed in which a pressurizing member supporting a piezoelectric element while applying a pressure to the piezoelectric element in the thickness direction thereof moves in an expansion and contraction direction of the piezoelectric element along with the piezoelectric element (for example, see JP-A-2007-189900).

In JP-A-8-237971 and WO2007/080851, there is a problem in that since the elastic member supporting the piezoelectric element is disposed to restrict vibration in a vibration direction of the piezoelectric element, particularly, in a bending vibration direction, the vibration of the piezoelectric element leaks from the elastic member to a supporting frame to lose drive energy of a driven object. In the structure disclosed in JP-A-2007-189900, there is a problem in that vibration leakage from a guide portion of a guide case is caused to lower a drive energy transmission efficiency to a driven object.

### SUMMARY

An advantage of some aspects of the invention is to solve at least a part of the problems described above, and the invention can be implemented as the following forms or application examples.

### Application Example 1

This application example is directed to a piezoelectric motor including: a piezoelectric element that vibrates by excitation of a bending vibration mode or vibrates by excitation of both the bending vibration mode and a longitudinal vibration mode; an upper support member that comes in surface contact with supporting portions distributed toward four corners of a first principal surface of the piezoelectric element; a pressing member that comes in surface contact with the surface of the upper support member facing the first principal surface; a lower support member that is disposed at a position plane-symmetric with respect to the upper support member with the piezoelectric element interposed therebetween and that comes in surface contact with the piezoelectric element; a machine casing member that comes in surface contact with the surface of the lower support member opposite to the contact surface thereof with the piezoelectric element; and an elastic member that presses a stacked body in which the machine casing member, the lower support member, the piezoelectric element, the upper support member, and the pressing member are sequentially stacked at positions of the supporting portions. According to this application example, since the supporting portions distributed toward four corners of the first principal surface of the piezoelectric element are interposed, pressed, and supported by the upper support member and the lower support member, it is possible to satisfactorily support the piezoelectric element and to suppress vibration leakage to the upper support member and the lower support member, thereby enhancing drive energy transmission efficiency to a driven object.

### Application Example 2

In the piezoelectric motor according to the above-mentioned application example, it is preferable that the supporting portions are arranged in a range around a line passing through nodes of secondary bending vibration of the piezoelectric element and being perpendicular to the longitudinal vibration of the piezoelectric element.

The piezoelectric element according to this application example has a primary longitudinal vibration mode and a secondary bending vibration mode. The displacement of the piezoelectric element at the positions in the line, which passes through the nodes of the secondary bending vibration and is perpendicular to the longitudinal vibration of the piezoelectric element, is smaller than that at the other positions. Accordingly, when the piezoelectric element is pressed and supported at these positions, it is possible to suppress vibration leakage to the upper support member and the lower support member.

### Application Example 3

In the piezoelectric motor according to the above-mentioned application example, it is preferable that excitation electrodes are formed at positions corresponding to the supporting portions on the first principal surface of the piezoelectric element, a common electrode is formed on a second principal surface of the piezoelectric element opposite to the first principal surface, unevenness is formed on a contact surface of the upper support member with the excitation electrodes, and unevenness is formed on a contact surface of the lower support member with the common electrode.

According to this application example, when the upper support member and the lower support member are pressed with the piezoelectric element interposed therebetween by the elastic member, the unevenness of the upper support member is transferred to the excitation electrodes and the unevenness of the lower support member is transferred to the common electrode. Accordingly, it is possible to increase the frictional force of the contact surfaces and thus to more satisfactorily hold the piezoelectric element, thereby further suppressing vibration leakage.

### Application Example 4

In the piezoelectric motor according to the above-mentioned application example, it is preferable that excitation electrodes are formed at positions corresponding to the supporting portions on the first principal surface of the piezoelectric element, a common electrode is formed on a second principal surface of the piezoelectric element, unevenness is formed on a contact surface of the excitation electrodes with the upper support member, and unevenness is formed on a contact surface of the common electrode with the lower support member. According to this application example, since the unevenness of the excitation electrodes is transferred to the upper support member and the unevenness of the common electrode is transferred to the lower support member, it is possible to increase the frictional force of the contact surfaces and thus to more satisfactorily hold the piezoelectric element, thereby further suppressing vibration leakage.

### Application Example 5

In the piezoelectric motor according to the above-mentioned application example, it is preferable that excitation electrodes are formed at positions corresponding to the supporting portions on the first principal surface of the piezoelectric element, a common electrode is formed on a second principal surface of the piezoelectric element, unevenness is formed on both contact surfaces of the upper support member and the excitation electrodes, and unevenness is formed on both contact surfaces of the lower support member and the common electrode.

In this way, by forming unevenness in both the excitation electrodes and the upper support member and forming unevenness in both the common electrode and the lower support member, it is possible to more satisfactorily hold the piezoelectric element and thus to further suppress vibration leakage. This configuration is effective in a case where the contact surfaces are substantially equal to each other in hardness.

### Application Example 6

In the piezoelectric motor according to the above-mentioned application example, it is preferable that unevenness is formed on one or both of the contact surfaces of the upper support member and the excitation electrodes and the contact surfaces of the lower support member and the common electrode, and unevenness is formed on one or both of the contact surfaces of the upper support member and the pressing member and on one or both of the contact surfaces of the lower support member and the machine casing member.

According to this application example, by forming unevenness on the contact surfaces of the upper support member and the pressing member and the contact surfaces of the lower support member and the machine casing member in addition to the unevenness formed on the contact surfaces with the piezoelectric element, it is possible to increase the frictional force in the contact surfaces of the upper support member and the pressing member and the contact surfaces of the lower support member and the machine casing member and it is thus to more satisfactorily hold the piezoelectric element, thereby further suppressing vibration leakage.

### Application Example 7

This application example is directed to a drive unit including: the piezoelectric motor according to any one of the above-mentioned application example; an elastic member that impels the protrusion to a driven object; and the driven object that is driven by an elliptic motion of the protrusion.

According to this application example, by employing the piezoelectric motor with reduced vibration leakage as described above, it is possible to enhance the drive energy transmission efficiency to the driven object, thereby realizing a drive unit with high efficiency.

### Application Example 8

It is preferable that the drive unit according to the above-mentioned application example includes the piezoelectric motor according to any one of the above-mentioned application examples and a driven object that has a contact surface coming in contact with the protrusion and a rotation axis perpendicular to the first principal surface or parallel to the first principal surface.

According to this application example, when a driven object has a rotation axis perpendicular to the longitudinal vibration direction, the driven object of a cylindrical shape can be made to rotate by pressing and driving the side surface of the driven object through the use of the protrusion. When a driven object has a rotation axis parallel to the longitudinal vibration direction, the driven object of a disk shape can be made to rotate by pressing and driving the plane of the driven object through the use of the protrusion.

### Application Example 9

It is preferable that the drive unit according to the above-mentioned application example includes the piezoelectric motor according to any one of the above-mentioned application examples and a driven object that has a straight guide rail supporting the driven object and a contact surface coming in contact with the protrusion and that is movable along the guide rail.

According to this application example, it is possible to efficiently drive the driven object along the guide rail in a linear manner.

### Application Example 10

It is preferable that the drive unit according to the above-mentioned application example includes the piezoelectric motor according to any one of the above-mentioned application examples, a fixed rail of which a surface in contact with the protrusion extends straightly, and an elastic member that impels the protrusion to the fixed rail, and the piezoelectric motor may be movable along the fixed rail by the elliptic motion of the protrusion.

According to this application example, the piezoelectric motor itself can move along the fixed rail relative to the fixed rail. Therefore, for example, when the piezoelectric motor is provided with a device cutting a rolled paper as another functional mechanism, it is possible to cause the cutting device or the like to efficiently move at a predetermined speed and in a predetermined direction.

### Application Example 11

This application example is directed to a robot including: an arm; a joint that is linked to the arm; and the drive unit according to the above-mentioned application example that is disposed in the joint.

According to this application example, by employing the drive unit having high drive energy transmission efficiency without vibration leakage, it is possible to realize a robot which can drive an arm with high efficiency. In a robot hand having fingers gripping a workpiece, when the fingers are constructed as small arms and the above-mentioned drive unit is used in the joints of the fingers, it is possible to realize driving of a robot hand with a reduced size and high efficiency.

### Application Example 12

This application example is directed to an electronic component transporting apparatus including: a gripper that grips an electronic component; an X-axis drive unit that causes the gripper to move in an X-axis direction; and a Y-axis drive unit that causes the gripper to move in a Y-axis direction perpendicular to the X-axis direction, wherein the X-axis drive unit and the Y-axis drive unit employ the drive unit according to Application Example 10.

According to this application example, by employing the drive unit having high drive energy transmission efficiency without vibration leakage, it is possible to realize an electronic component transporting apparatus which can drive a gripper with high efficiency.

### Application Example 13

This application example is directed to an electronic component inspecting apparatus including: an inspection unit that inspects an inspected object; a first drive unit that causes the inspection unit to move in an X-axis direction; and a second drive unit that causes the inspection unit to move in a Y-axis direction perpendicular to the X-axis direction, wherein the first drive unit and the second drive unit employ the drive unit according to Application Example 10.

According to this application example, since the drive unit can decrease in size and weight, it is possible to realize an electronic component inspecting apparatus which has a small driving load and which can cause the inspection unit to rapidly and accurately move to the position of the inspected object through the use of the drive unit.

### Application Example 14

This application example is directed to a printer including: a transport mechanism that transports a recording medium; an ejection head that ejects droplets to the recording medium; and the drive unit according to the application example 10 that is movable in a direction perpendicular to the transport direction of the recording medium.

According to this application example, by employing the above-mentioned drive unit, it is possible to implement a printer with reduced size and weight and with a small drive load.

### BRIEF DESCRIPTION OF THE DRAWINGS

The invention will be described with reference to the accompanying drawings, wherein like numbers reference like elements.

FIG. 1 is a plan view illustrating a piezoelectric motor.

FIG. 2 is a cross-sectional view taken along line D-D of FIG. 1.

FIGS. 3A to 3D are diagrams schematically illustrating the configuration and driving method of a piezoelectric element, where FIG. 3A is a plan view when the piezoelectric element stops, FIGS. 3B and 3C illustrate vibration of the piezoelectric element and the driving method of a driven object, and FIG. 3D schematically illustrates a combination of the vibration shown in FIG. 3B and the vibration shown in FIG. 3C.

FIG. 4 is a plan view illustrating the relationship between supporting portions of the piezoelectric element and support members.

FIG. 5 is a cross-sectional view schematically illustrating a pressing and supporting structure of the piezoelectric element.

FIGS. 6A to 6D are diagrams schematically illustrating a first example of the piezoelectric motor, where FIG. 6A is a cross-sectional view illustrating a state before the piezoelectric element is pressed, FIG. 6B is a cross-sectional view partially illustrating a state where the piezoelectric element is pressed, and FIGS. 6C and 6D are a cross-sectional view and a plan view illustrating shape examples of unevenness, respectively.

FIGS. 7A to 7C are diagrams schematically illustrating a part of a second example of the piezoelectric motor, where FIG. 7A is a cross-sectional view illustrating a state before the piezoelectric element is pressed, FIG. 7B is a plan view illustrating a shape example of the unevenness, and FIG. 7C is a cross-sectional view illustrating a state where the piezoelectric element is pressed.

FIGS. 8A to 8D are plan views illustrating shapes of a first support member and a second support member according to a modification example, where FIG. 8A illustrates Modification Example 1, FIG. 8B illustrates Modification Example 2, FIG. 8C illustrates Modification Example 3, and FIG. 8D illustrates Modification Example 4.

FIG. 9 is a cross-sectional view schematically illustrating a part of a fourth example of the piezoelectric motor.

FIGS. 10A and 10B are diagrams illustrating a first example of a drive unit, where FIG. 10A is a plan view and FIG. 10B is a cross-sectional view taken along line E-E of FIG. 10A.

FIGS. 11A and 11B are diagrams illustrating a second example of the drive unit, where FIG. 11A is a plan view and FIG. 11B is a cross-sectional view taken along line F-F of FIG. 11A.

FIG. 12 is a perspective view schematically illustrating the configuration of a robot.

FIG. 13 is a diagram schematically illustrating the appearance of a robot hand.

FIG. 14 is a perspective view illustrating an example of an electronic component inspecting apparatus.

FIG. 15 is a perspective view schematically illustrating the configuration of a printer.

FIG. 16 is a cross-sectional view illustrating an example of a cutting unit.

### DESCRIPTION OF EXEMPLARY EMBODIMENTS

Hereinafter, embodiments of the invention will be described with reference to the accompanying drawings.

In the drawings which are mentioned in the following description, vertical and horizontal scales of members and portions are different from actual scales, for the purpose of enabling recognition of the members.

### Piezoelectric Motor

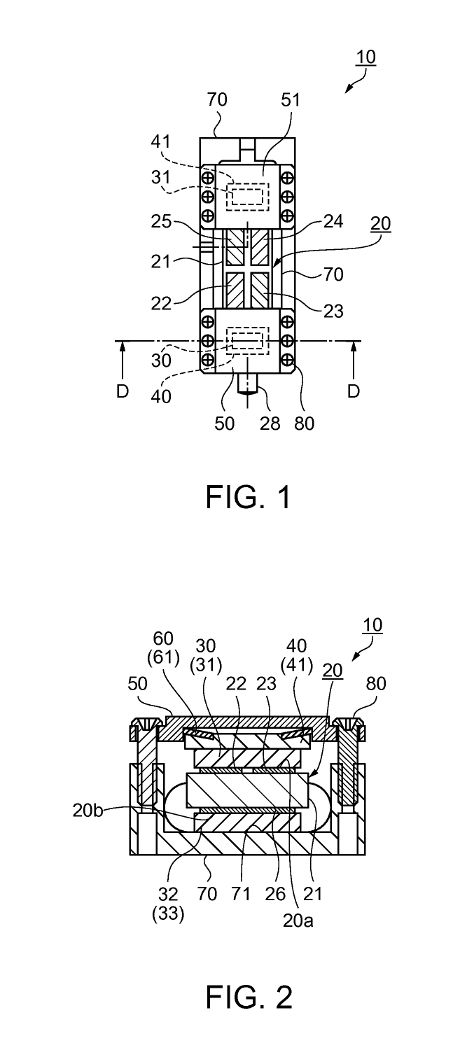

FIG. 1 is a plan view illustrating a piezoelectric motor 10. FIG. 2 is a cross-sectional view taken along line D-D of FIG. 1. In FIGS. 1 and 2, the piezoelectric motor 10 includes a piezoelectric element 20 that has a rectangular plane and drives a driven object through in-plane vibration, and a first support member 30 and a second support member 31 that come in contact with supporting portions distributed toward four corners of a first principal surface 20a of the piezoelectric element 20. The first support member 30 and the second support member 31 are referred to as an upper support member.

The piezoelectric motor 10 further includes a pressing member having a first pressing plate 40 pressing the first support member 30 and a second pressing plate 41 pressing the second support member 31, a third support member 32 that comes in contact with a second principal surface 20b of the piezoelectric element 20 opposite to the first principal surface 20a and that is disposed at a position which is plane-symmetric with respect to the first support member 30 with the piezoelectric element 20 interposed therebetween, and a fourth support member 33 that is disposed at a position which is plane-symmetric with respect to the second support member 31. The third support member 32 and the fourth support member 33 are referred to as a lower support member. The piezoelectric motor 10 further includes a case 70 as a machine casing member pressing the lower support member to the piezoelectric element 20.

The piezoelectric motor 10 further includes a first pressing spring 60 and a second pressing spring 61 as an elastic member that presses, at the positions of the supporting portions, a stacked body in which the lower support member (the third support member 32 and the fourth support member 33), the piezoelectric element 20, the upper support member (the first support member 30 and the second support member) 31), and the pressing member (the first pressing plate 40 and the second pressing plate 41) are sequentially stacked on the case bottom surface 71 of the case 70.

The first pressing spring 60 is interposed between the first pressing plate 40 and a first fixed plate 50, and presses the first support member 30 and the third support member 32 to the piezoelectric element 20 by fastening a fixing screw 80 to the case 70.

The second pressing spring 61 is interposed between the second pressing plate 41 and a second fixed plate 51, and presses the second support member 31 and the fourth support member 33 to the piezoelectric element 20 by fastening a fixing screw 80 to the case 70. FIG. 2 shows an initial state where the stacked body is not pressed by the first pressing spring 60 and the second pressing spring 61.

At this time, as shown in FIG. 2, a gap in the thickness direction is present between the first fixed plate 50 and the second fixed plate 51 and the case 70. This is to absorb a difference in thickness between the elements with the first pressing spring 60 and the second pressing spring 61 when the piezoelectric element 20, the upper support member, the lower support member, the first pressing plate 40, and the second pressing plate 41 are stacked. In this embodiment, the pressing force of the first pressing spring 60 and the second pressing spring 61 is about several kg.

A protrusion 28 is formed at an end on the short side of the piezoelectric element 20. The protrusion 28 comes in contact with a driven object to drive the driven object with a frictional force and is thus formed of a material having a high frictional coefficient with the driven object and high abrasion resistance. The protrusion 28 is formed of a hard material such as zirconia and ceramic. The protrusion 28 moves elliptically by the bending vibration of the piezoelectric element 20 to drive the driven object.

The configuration and the driving method of the piezoelectric element 20 used in the piezoelectric motor 10 according to this embodiment will be described below.

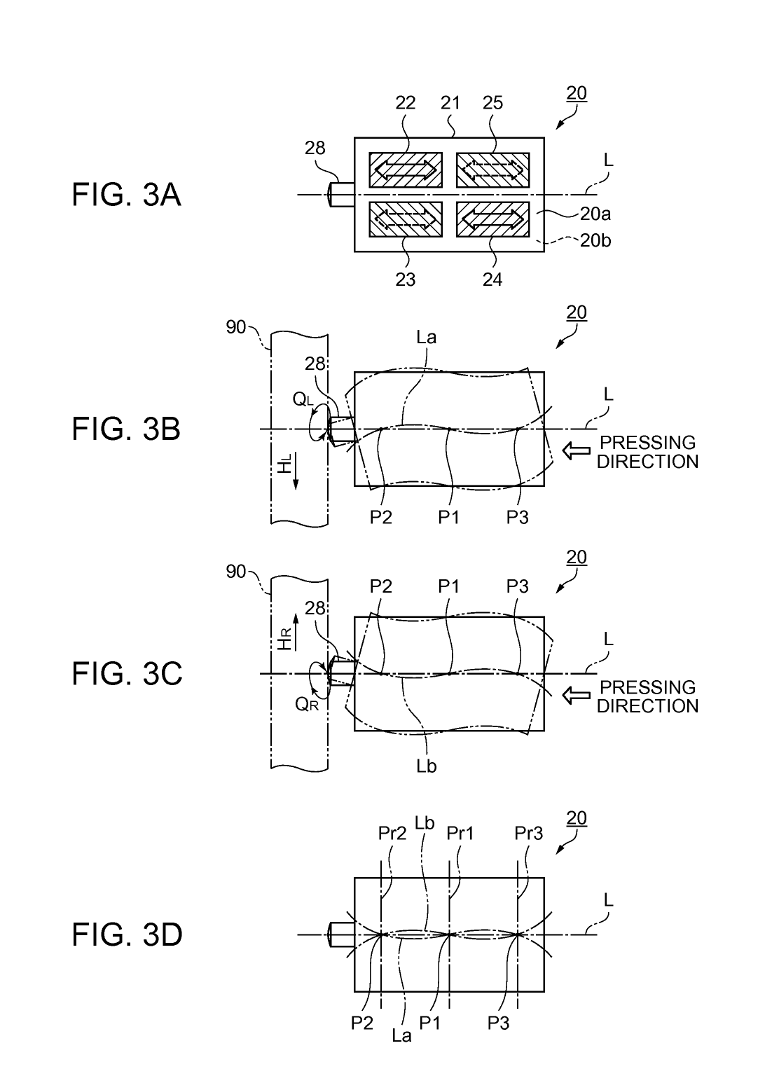

FIGS. 3A to 3D are diagrams schematically illustrating the configuration and the driving method of the piezoelectric element 20, where FIG. 3A is a plan view when the piezoelectric element stops, FIGS. 3B and 3C illustrate the vibration of the piezoelectric element 20 and the driving method of a driven object, and FIG. 3D schematically illustrates a combination of the vibration shown in FIG. 3B and the vibration shown in FIG. 3C.

In FIG. 3A, in the piezoelectric element 20, a first excitation electrode 22, a second excitation electrode 23, a third excitation electrode 24, and a fourth excitation electrode 25 are formed on the first principal surface 20a of a piezoelectric body 21. On the second principal surface 20b opposite to the first principal surface 20a, a common electrode 26 (see FIG. 2) is formed on the substantially entire surface of the second principal surface 20b of the piezoelectric body 21.

The material of the piezoelectric body 21 is not particularly limited, as long as it is a material having a piezoelectric property. For example, PZT (Piezoelectric Zirconate Titanate) can be suitably used. The material of the first excitation electrode 22, the second excitation electrode 23, the third excitation electrode 24, the fourth excitation electrode 25, and the common electrode 26 is not particularly limited, as long as it is conductive metal. These electrodes can be formed by applying an Ag paste using a screen printing method or applying Al, Au, W, Cu, Ag, and the like using a sputtering method or a vapor deposition method.

The first excitation electrode 22 and the third excitation electrode 24 are electrically connected to each other and the second excitation electrode 23 and the fourth excitation electrode 25 are electrically connected to each other. According to this electrode configuration, longitudinal vibration is excited in which the piezoelectric body 21 expands (which is indicated by a solid arrow) when a voltage is applied to the first excitation electrode 22 and the third excitation electrode 24 and is restored when the voltage supply is stopped. On the other hand, longitudinal vibration is excited in which the piezoelectric body 21 expands (which is indicated by a dotted arrow) when a voltage is applied to the second excitation electrode 23 and the fourth excitation electrode 25 and is restored when the voltage supply is stopped.

In this way, by applying a voltage to the first excitation electrode 22 and the third excitation electrode 24 or the second excitation electrode 23 and the fourth excitation electrode 25, bending vibration is excited in the piezoelectric element 20. The bending vibration excited in this way will be described below with reference to FIGS. 3B, 3C, and 3D.

FIG. 3B illustrates a state where a voltage is applied to the first excitation electrode 22, the third excitation electrode 24, and the common electrode 26 and a voltage is not applied to the second excitation electrode 23 and the fourth excitation electrode 25. In this state, the longitudinal vibration is excited in the range in which the first excitation electrode 22 and the third excitation electrode 24 are formed (see FIG. 3A). However, since a voltage is not applied to the second excitation electrode 23 and the fourth excitation electrode 25, the longitudinal vibration is not excited therein. As a result, as shown in FIG. 3B, secondary bending vibration is excited in the planes of the first principal surface 20a and the second principal surface 20b of the piezoelectric element 20. As a result, the protrusion 28 elliptically moves in the arrow direction in an elliptic orbit Q_{L} shown in the drawing. Since the protrusion 28 is pressed to the driven object 90, the driven object 90 coming in contact therewith is made to move in the direction of H_{L} with the elliptic motion in the direction of Q_{L} of the protrusion 28.

As shown in FIG. 3B, the central axis of the bending vibration is represented by L, the nodes of the vibration are represented by P1, P2, and P3, and the vibration mode is represented by La.

In the contact portion between the protrusion 28 and the driven object 90, a driving force based on the frictional force of the contact portion is generated for the driven object 90 along the elliptic orbit Q_{L} of the protrusion 28. The driven object 90 is driven in the direction of H_{L} by this driving force. FIG. 3C illustrates a state where a voltage is applied to the second excitation electrode 23, the fourth excitation electrode 25, and the common electrode 26 and a voltage is not applied to the first excitation electrode 22 and the third excitation electrode 24. In this state, the longitudinal vibration is excited in the range in which the second excitation electrode 23 and the fourth excitation electrode 25 are formed (see FIG. 3A). However, since a voltage is not applied to the first excitation electrode 22 and the third excitation electrode 24, the longitudinal vibration is not excited therein. As a result, as shown in FIG. 3C, secondary bending vibration is excited in the planes of the first principal surface 20a and the second principal surface 20b of the piezoelectric element 20. The secondary bending vibration shown in FIG. 3C has a phase opposite to the phase of the secondary bending vibration shown in FIG. 3B. As a result, the protrusion 28 elliptically moves in the arrow direction in an elliptic orbit Q_{R} shown in the drawing. Since the protrusion 28 is pressed to the driven object 90, the driven object 90 is made to move in the direction of H_{R} with the elliptic motion in the direction of Q_{R} of the protrusion 28.

As shown in FIG. 3C, the central axis of the bending vibration is represented by L, the nodes of the vibration are represented by P1, P2, and P3, and the vibration mode is represented by Lb.

In the contact portion between the protrusion 28 and the driven object 90, a driving force based on the frictional force in the contact portion is generated for the driven object 90 along the elliptic orbit Q_{R} of the protrusion 28. The driven object 90 is driven in the direction of H_{R} by this driving force. In this way, by switching the voltage supply to the first excitation electrode 22 and the third excitation electrode 24 and the voltage supply to the second excitation electrode 23 and the fourth excitation electrode 25 to each other, it is possible to change the bending vibration direction of the piezoelectric element 20 and thus to easily switch the driving direction of the driven object 90.

The nodes of vibration in two vibration modes of the bending vibration and the longitudinal vibration of the piezoelectric element 20 will be described below with reference to FIG. 3D. FIG. 3D is a diagram illustrating the concept of the vibration modes of the piezoelectric element 20. As shown in FIG. 3D, the piezoelectric element 20 illustrates the vibration modes La and Lb which are described above with reference to FIGS. 3B and 3C. When the vibration modes La and Lb are combined, the nodes of vibration P1, P2, and P3 are present in the central axis L of the vibration.

In the areas including lines Pr1, Pr2, and Pr3 (hereinafter, referred to as nodal lines Pr1, Pr2, and Pr3) passing through the nodes of vibration P1, P2, and P3 and extending in the direction perpendicular to the longitudinal vibration of the piezoelectric element 20, the displacement of the piezoelectric element 20 is smaller than those in the other positions. Therefore, the supporting portions pressing and supporting the piezoelectric element 20 are preferably disposed in the areas including the nodal lines Pr1, Pr2, and Pr3, and more preferably in the areas including the nodes of vibration P2 and P3 closest to the outline of the piezoelectric element 20.

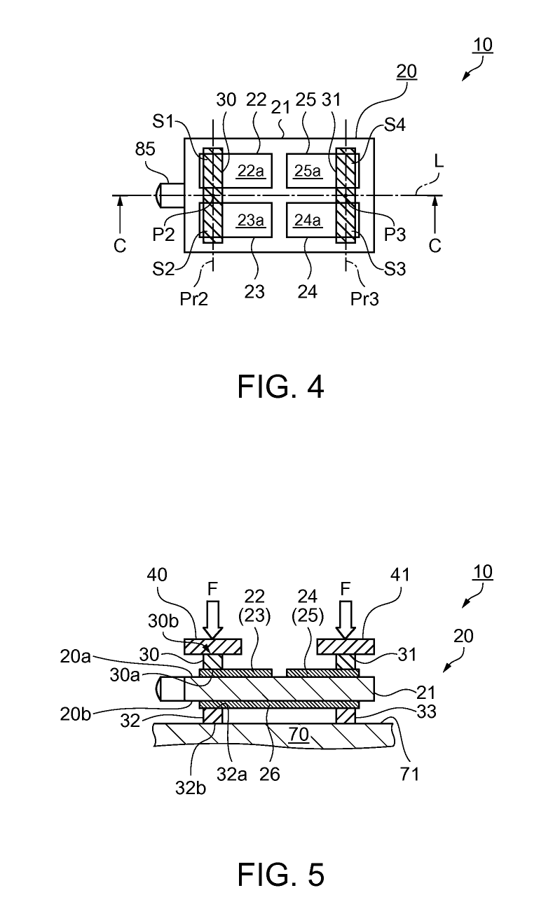

Subsequently, the pressing and supporting structure of the piezoelectric element 20 will be described with reference to FIGS. 4 and 5.

FIG. 4 is a plan view illustrating the relationship between the supporting portions S1, S2, S3, and S4 of the piezoelectric element 20 and the support members. Here, the first support member 30 is disposed over the first excitation electrode 22 and the second excitation electrode 23 in the nodal line Pr2. The area in which the first support member 30 and the first excitation electrode 22 intersect each other is the support portion S1, and the area in which the first support member 30 and the second excitation electrode 23 intersect each other is the supporting portion S2. The third support member 32 is disposed to be plane-symmetric with respect to the first support member 30 with the piezoelectric element 20 interposed therebetween.

On the other hand, the second support member 31 is disposed to extend over the third excitation electrode 24 and the fourth excitation electrode 25 in the nodal line Pr3. The area in which the second support member 31 and the third excitation electrode 24 intersect each other is the support portion S3, and the area in which the second support member 31 and the fourth excitation electrode 25 intersect each other is the supporting portion S4. The fourth support member 33 is disposed to be plane-symmetric with respect to the second support member 31 with the piezoelectric element 20 interposed therebetween. As described above, the supporting portions S1, S2, S3, and S4 are arranged toward four corners of the piezoelectric element 20.

The piezoelectric element 20 according to this embodiment is a flat rectangular parallelepiped with a length of 30 mm, a width of 7.5 mm, and a thickness of 3.0 mm, and allows a decrease in size and weight of the piezoelectric motor 10 in comparison with other steps motors or servo motors.

FIG. 5 is a cross-sectional view schematically illustrating the pressing and supporting structure of the piezoelectric element 20 and illustrates a cross-section taken along line C-C of FIG. 4. As shown in FIG. 5, the piezoelectric element 20 is pressed and supported at the positions of the supporting portions S1, S2, S3, and S4 (see FIG. 4) with a pressing force F by the first pressing spring 60 and the second pressing spring 61 (not shown in the drawing), in a state where the third support member 32 and the fourth support member 33 are disposed on the case bottom surface 71, the piezoelectric element 20 is stacked on the third support member 32 and the fourth support member 33, the first support member 30 and the second support member 31 are stacked on the piezoelectric element 20, and the first pressing plate 40 and the second pressing plate 41 are staked thereon.

More specifically, as shown in FIGS. 4 and 5, the first support member 30 comes in surface contact with the surface 22a of the first excitation electrode 22 and the surface 23a of the second excitation electrode 23, and the second support member 31 comes in surface contact with the surface 24a of the third excitation electrode 24 and the surface 25a of the fourth excitation electrode 25. The third support member 32 and the fourth support member 33 come in surface contact with the surface 26a of the common electrode 26. For the purpose of pressing and supporting of the piezoelectric element 20, unevenness are preferably formed on the contact surfaces of the elements to enhance the frictional force therebetween.

A structure may be employed in which the first support member 30 and the second support member 31 are formed as a body to constitute an upper support member and protruding portions pressing the first supporting portion S1, the second supporting portion S2, the third supporting portion S3, and the fourth supporting portion S4, respectively, are formed on the upper support member.

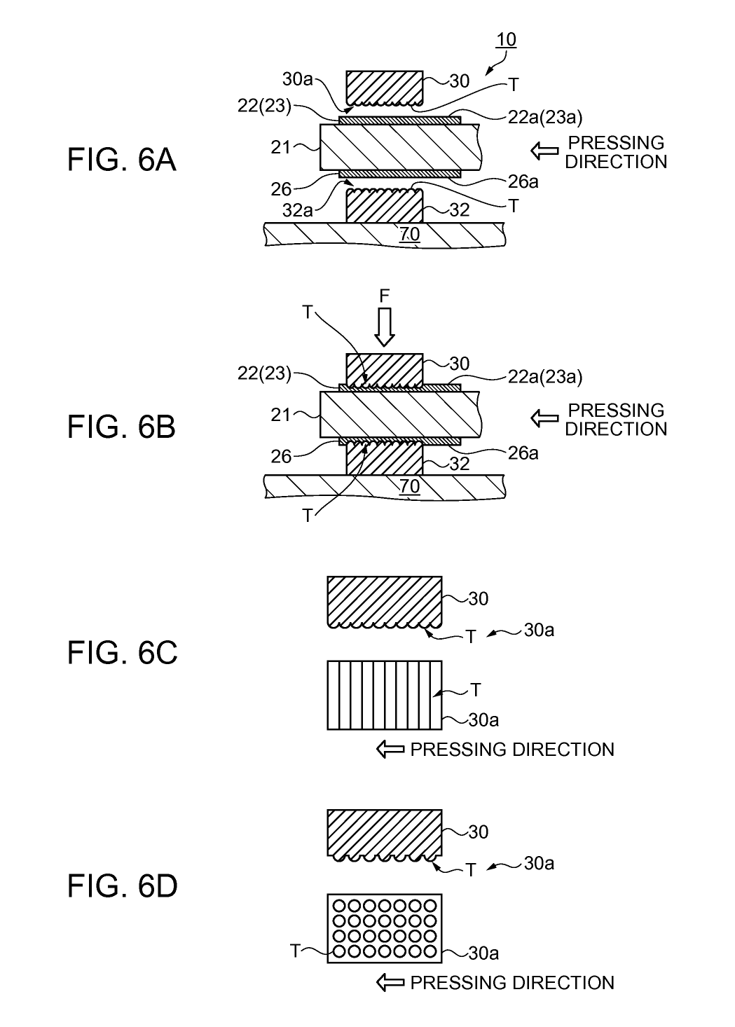

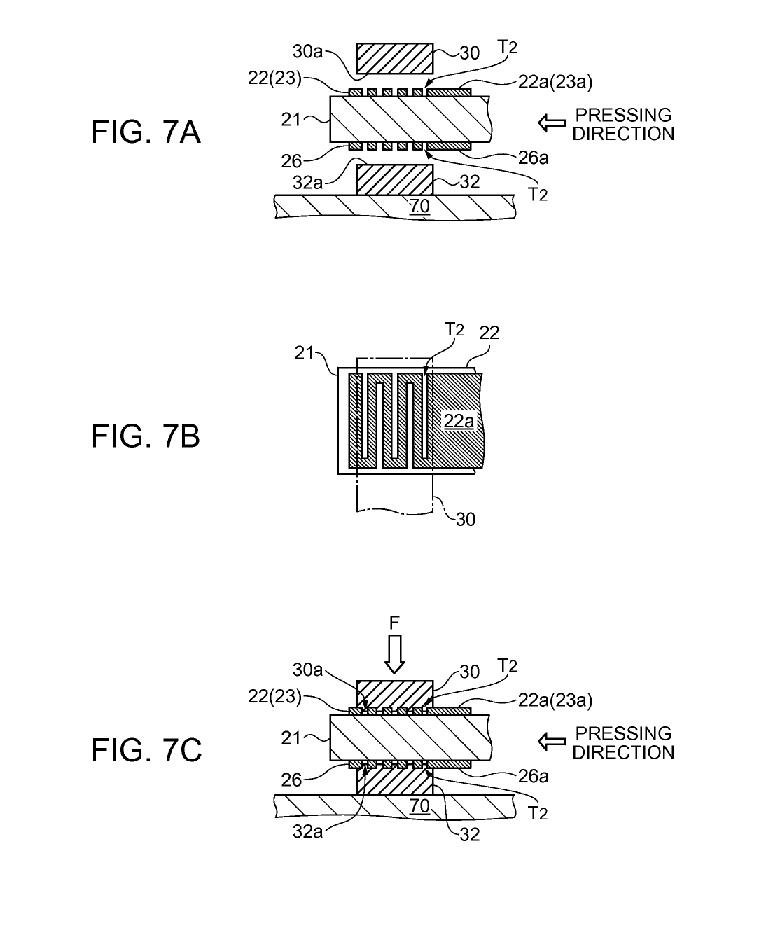

The configuration of the contact surface of each element will be described below with reference to examples shown in FIGS. 6A to 6D and FIGS. 7A to 7C.

### First Example

FIGS. 6A to 6D are diagrams schematically illustrating a first example of the piezoelectric motor, where FIG. 6A is a cross-sectional view illustrating a state before the piezoelectric element is pressed and FIG. 6B is a cross-sectional view partially illustrating a state where the piezoelectric element is pressed. In this example, unevenness T is formed on the contact surfaces of the first support member 30, the second support member 31, the third support member 32, and the fourth support member 33 with the piezoelectric element 20. FIGS. 6C and 6D show the shapes of the unevenness T. Since the first support member 30, the second support member 31, the third support member 32, and the fourth support member 33 have almost the same configuration, the first support member 30 and the third support member 32 opposed to the first support member 30 will be exemplified below.

As shown in FIG. 6A, the unevenness T is formed on the surface 30a of the first support member 30 coming in contact with the piezoelectric element 20 and the surface 32a of the third support member 32 coming in contact with the piezoelectric element 20. In this example, the first support member 30, the second support member 31, the third support member 32, and the fourth support member 33 are formed of polyimide or ABS resin, and are formed to have a rectangular parallelepiped shape with a length of 5.0 mm, a width of 6.5 mm, and a thickness of 1.0 mm. The first excitation electrode 22, the second excitation electrode 23, the third excitation electrode 24, the fourth excitation electrode 25, and the common electrode 26 are formed of an Ag paste.

As shown in FIG. 6B, when the first support member 30 and the third support member 32 are pressed with a pressing force F, the unevenness T of the first support member 30 bites into the surfaces 22a and the 23a of the excitation electrodes 22 and 23 so as to be transferred thereto. The unevenness T of the third support member 32 bites into the surface 26a of the common electrode 26 so as to be transferred thereto.

In this way, the unevenness T of the first support member 30 and the third support member 32 bites into the surfaces of the electrodes to raise the frictional force of the contact surfaces. The unevenness T may have various shapes and thus representative examples will be described below.

FIG. 6C shows an example where unevenness T is linearly formed, where a cross-sectional view is shown on the upper side and a plan view is shown on the lower side. The unevenness T is formed in line shapes in the direction perpendicular to the longitudinal vibration direction of the piezoelectric element 20. The unevenness T is formed using a file, a sand paper, a hard transfer mold, or the like. The pitch or depth of the unevenness T is determined depending on the surface hardness of the opponent electrodes.

FIG. 6D shows an example where unevenness T is formed in dot shapes, where a cross-sectional view is shown on the upper side and a plan view is shown on the lower side. The unevenness T may be arranged as shown in the drawing or randomly on the surface 30a of the first support member 30. The unevenness T is formed using a hard transfer mold or the like. The size, the shape, the number, and the depth of the unevenness T are determined depending on the surface hardness of the opponent electrodes.

The unevenness may be formed on the respective electrodes, which will be described below as a second example with reference to FIGS. 7A to 7C.

### Second Example

FIGS. 7A to 7C are diagrams schematically illustrating a part of a second example of the piezoelectric motor, where FIG. 7A is a cross-sectional view illustrating a state before the piezoelectric element is pressed, FIG. 7B is a plan view illustrating a shape example of the unevenness, and FIG. 7C is a cross-sectional view illustrating a state where the piezoelectric element is pressed. In this example, unevenness is formed on the first excitation electrode 22, the second excitation electrode 23, the third excitation electrode 24, the fourth excitation electrode 25, and the common electrode 26 formed on the piezoelectric element 20. The first support member 30, the first excitation electrode 22, the third support member 32, and the common electrode 26 will be exemplified. The same parts as in the first example (see FIGS. 6A to 6D) are referenced by the same reference numerals.

As shown in FIG. 7A, unevenness T is not formed in the first support member 30 and the third support member 32. On the other hand, unevenness T2 is formed on the first excitation electrode 22 and the common electrode 26.

As shown in FIG. 7B, the unevenness T2 is formed by patterning the first excitation electrode 22 in the area in which the first support member 30 and the first excitation electrode 22 intersect each other, that is, the area of the supporting portion S1. The same is true of the common electrode 26. The unevenness T2 can be easily formed in a desired shape through the use of a screen printing method, and the width and pitch of the portions corresponding to convex portions or concave portions are determined depending on the surface hardness of the support member.

As shown in FIG. 7C, when the piezoelectric element 20 is interposed and pressed with a pressing force F by the use of the first support member 30 and the third support member 32, the unevenness T2 of the first excitation electrode 22 bites into the surface 30a of the first support member 30 so as to be transferred thereto. The unevenness T2 of the common electrode 26 bites into the surface 32a of the third support member 32 so as to be transferred thereto. In this way, by causing the unevenness T2 of the electrodes to bite into the surfaces 30a and 32a of the support members, it is possible to enhance the frictional force of the contact surface. Here, combinations of materials satisfying surface hardness of support members≦hardness of electrodes are employed.

The shape of the unevenness T2 of the excitation electrode side and the shape of the unevenness T2 of the common electrode side may not be necessarily equal to each other.

In the piezoelectric motor 10, the first supporting portion S1, the second supporting portion S2, the third supporting portion S3, and the fourth supporting portion S4 distributed toward four corners of the piezoelectric element 20 are interposed, pressed, and supported with a balance by the first support member 30 and the second support member 31 which are the upper support member and the third support member 32 and the fourth support member 33 which are the lower support member. Accordingly, it is possible to satisfactorily support the piezoelectric element 20 and to suppress the vibration leakage, thereby enhancing the drive energy transmission efficiency to the driven object 90.

The first supporting portion S1 and the second supporting portion S2 are arranged in the area including the nodal line Pr2 passing through the node P2 of the secondary bending vibration of the piezoelectric element 20, and the third supporting portion S3 and the fourth supporting portion S4 are arranged in the area including the nodal line Pr3 passing through the node P3 of the secondary bending vibration of the piezoelectric element 20. In the nodal lines Pr2 and Pr3, the displacement of the piezoelectric element 20 is smaller than that of the other portion. Accordingly, when the piezoelectric element 20 is pressed and supported at the positions, it is possible to further suppress the vibration leakage.

The first excitation electrode 22 is disposed at the position at which the first supporting portion S1 is disposed on the first principal surface 20a, the second excitation electrode 23 is disposed at the position at which the second supporting portion S2 is disposed, the third excitation electrode 24 is disposed at the position at which the third supporting portion S3 is disposed, the fourth excitation electrode 25 is disposed at the position at which the fourth supporting portion S4 is disposed, and the common electrode 26 is disposed on the second principal surface of the piezoelectric element 20. The unevenness T is formed on the respective contact surfaces of the first support member 30, the second support member 31, the third support member 32, and the fourth support member 33 with the first excitation electrode 22, the second excitation electrode 23, the third excitation electrode 24, and the fourth excitation electrode 25. Since the unevenness T is transferred to the surfaces of the electrodes when pressing and supporting the piezoelectric element 20, it is possible to increase the frictional force of the contact surfaces and thus to satisfactorily support the piezoelectric element 20, thereby further suppressing the vibration leakage.

On the contrary, by disposing the first excitation electrode 22, the second excitation electrode 23, the third excitation electrode 24, and the fourth excitation electrode 25 and forming the unevenness T2 on the respective excitation electrodes, the unevenness T2 is transferred to the contact surfaces of the support members, thereby increasing the frictional force of the contact surfaces.

### Third Example

In the first example, the unevenness T is formed on the first support member 30, the second support member 31, the third support member 32, and the fourth support member 33. In the second example, the unevenness T2 is formed on the first excitation electrode 22, the second excitation electrode 23, the third excitation electrode 24, and the fourth excitation electrode 25. However, unevenness may be formed on both contact surfaces of the support members and the electrodes. Although not shown in the drawings, for example, unevenness T described in the first example (see FIGS. 6C and 6D) is formed on the contact surfaces of the first support member 30, the second support member 31, the third support member 32, and the fourth support member 33 with the piezoelectric element 20. Unevenness T2 described in the second example (see FIG. 7B) is formed on the contact surfaces of the first excitation electrode 22, the second excitation electrode 23, the third excitation electrode 24, the fourth excitation electrode 25, and the common electrode 26 with the first support member 30, the second support member 31, the third support member 32, and the fourth support member 33.

In this way, when the unevenness T or the unevenness T2 is formed on both contact surfaces of the first excitation electrode 22, the second excitation electrode 23, the third excitation electrode 24, the fourth excitation electrode 25, and the common electrode 26 and the first support member 30, the second support member 31, the third support member 32, and the fourth support member 33, it is possible to more satisfactorily support the piezoelectric element 20 and thus to further suppress the vibration leakage. This configuration is very effective when the contact surfaces are almost equal to each other in hardness.

In the first to third examples, the planar shape of the first support member 30, the second support member 31, the third support member 32, and the fourth support member 33 is rectangular and the supporting portions S1 to S4 are rectangular. However, since the shapes are not limited to rectangular but various shapes can be used, the shapes will be shown and described below as modification examples. The same elements as in the first example will be referenced by the same reference numerals.

### Modification Examples

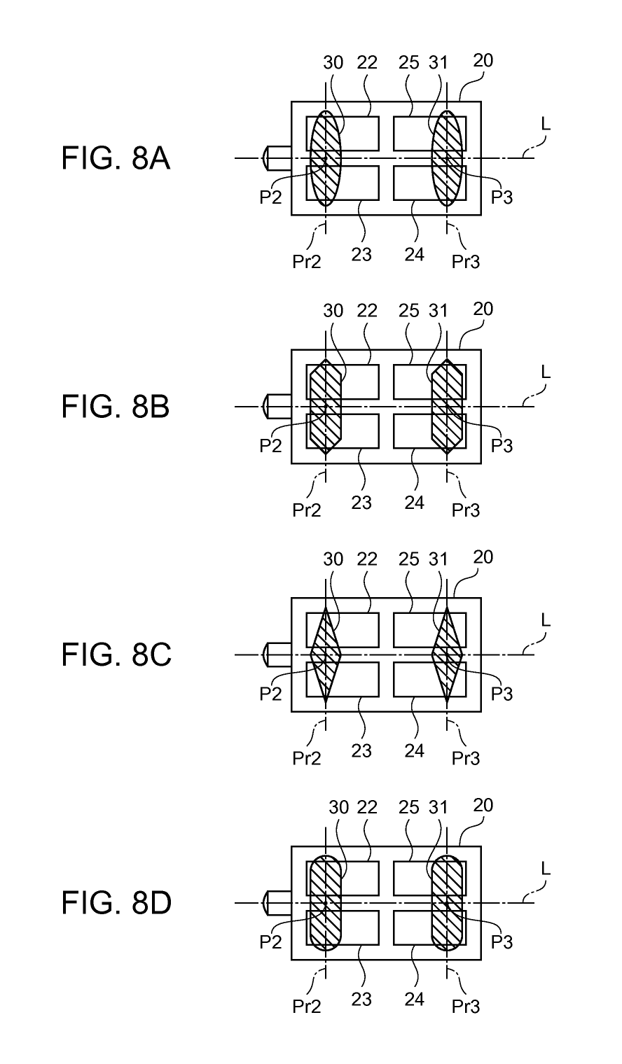

FIGS. 8A to 8D are plan views illustrating shapes of the first support member 30 and the second support member 31 according to modification examples, where FIG. 8A illustrates Modification Example 1, FIG. 8B illustrates Modification Example 2, FIG. 8C illustrates Modification Example 3, and FIG. 8D illustrates Modification Example 4. The shapes of the third support member 32 and the fourth support member 33 are set to be equal to the shape of the first support member 30. Therefore, the first support member 30 and the second support member 31 will be exemplified below.

In Modification Example 1, the contact surfaces of the first support member 30 and the second support member 31 with the piezoelectric element 20 are formed in an elliptic shape as shown in FIG. 8A. In Modification Example 2, the contact surfaces of the first support member 30 and the second support member 31 with the piezoelectric element 20 are formed in a modified hexagonal shape in which ends in the width direction of the piezoelectric element 20 are narrowed as shown in FIG. 8B. In Modification Example 3, the contact surfaces of the first support member 30 and the second support member 31 with the piezoelectric element 20 are formed in a rhombic shape as shown in FIG. 8C. In Modification Example 4, the contact surfaces of the first support member 30 and the second support member 31 with the piezoelectric element 20 are formed in a track shape as shown in FIG. 8D.

When these modification examples are employed, the same advantages are achieved by forming the unevenness T or the unevenness T2 described in the first to third examples.

### Fourth Example

A fourth example of the piezoelectric motor 10 will be described below. In the first to third examples, the unevenness T or the unevenness T2 is formed on one or both of the contact surfaces of the support members and the electrodes. However, in the fourth example, unevenness is additionally formed on the contact surfaces of the upper support member and the pressing plates and the contact surfaces of the lower support member and the case 70.

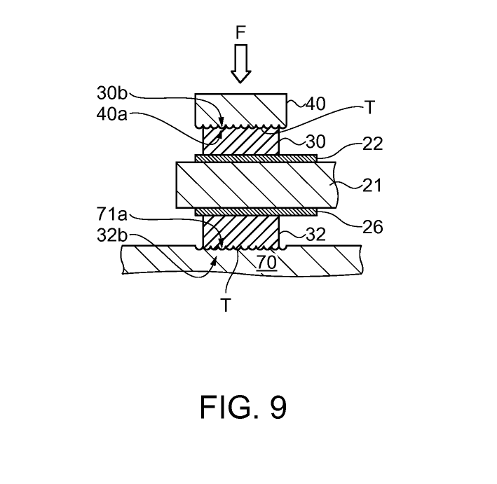

FIG. 9 is a cross-sectional view schematically illustrating a part of the fourth example. The first support member 30 which is one of the upper support members and the third support member 32 which is one of the lower support members will be exemplified. The same elements as in the first example will be referenced by the same reference numerals. Although not shown in FIG. 9, the unevenness T and the unevenness T2 shown in FIGS. 6A to 6D or FIGS. 7A to 7C are formed on one or both of the contact surfaces of the first support member 30 and the first excitation electrode 22 and on one or both of the contact surfaces of the third support member 32 and the common electrode 26.

In FIG. 9, the same unevenness T as described in the first example (see FIGS. 6C and 6D) is formed on the contact surface 40a of the first pressing plate 40 with the first support member 30. The same unevenness T3 as that of the first pressing plate 40 is formed on the contact surface 71a of the case bottom surface 71. As shown in FIG. 9, when the piezoelectric element 20 is pressed with a pressing force F via the first support member 30 and the third support member 32 by the use of the first pressing plate 40 and the case 70, the unevenness T of the first pressing plate 40 bites into the contact surface 30b of the first support member 30 so as to be transferred thereto. The unevenness T of the case bottom surface 71 bites into the contact surface 32b of the third support member 32 so as to be transferred thereto.

The unevenness T may be formed on the contact surface 30b of the first support member 30 with the first pressing plate 40 or may be formed on the contact surface 32b of the third support member 32 with the case bottom surface 71.

By employing this configuration, in addition to the unevenness T or the unevenness T2 described in the first to third examples, the unevenness T is formed on the contact surface of the first support member 30 with the first pressing plate 40 and the contact surface of the second support member 31 with the second pressing plate 41, and the unevenness T is formed on the contact surfaces of the third support member 32 and the fourth support member 33 with the case bottom surface 71. Therefore, it is possible to raise the frictional force in the contact surfaces and thus to more satisfactorily support the piezoelectric element 20, thereby further suppressing the vibration leakage.

### First Example of Drive Unit

A drive unit 100 using the above-mentioned piezoelectric motor 10 will be described below.

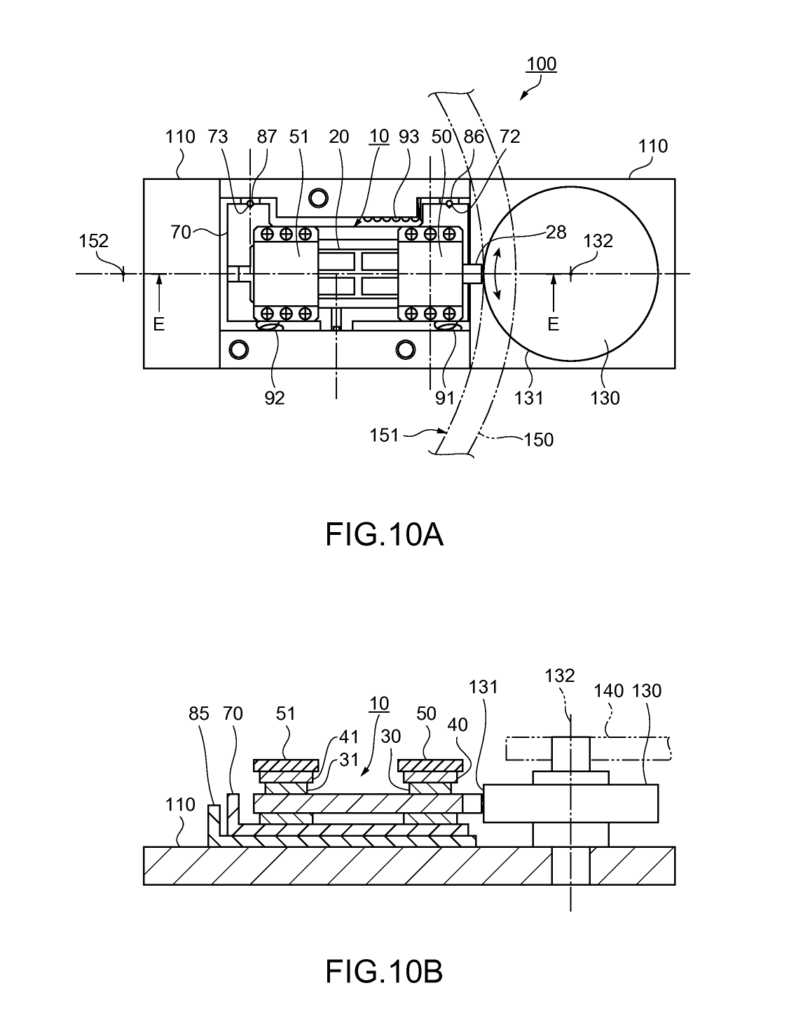

FIGS. 10A and 10B are diagrams illustrating a first example of a drive unit, where FIG. 10A is a plan view and FIG. 10B is a cross-sectional view taken along line E-E of FIG. 10A. The drive unit 100 according to this example includes the piezoelectric motor 10 described in the first to fourth examples, a contact surface 131 coming in contact with the protrusion 28 of the piezoelectric motor 10, and a rotor 130 as a driven object having a rotation axis 132 perpendicular to the longitudinal vibration direction of the piezoelectric motor 10.

Here, the rotation axis 132 perpendicular to the longitudinal vibration direction of the piezoelectric motor 10 may be replaced with a rotation axis 132 perpendicular to the first principal surface 20a (or the second principal surface 20b) of the piezoelectric motor 10.

The piezoelectric motor 10 is mounted on a base 110 in a state where it is disposed in the machine casing 85. The rotor 130 is axially supported by the base 110 and an upper base 140. Notches 72 and 73 are formed on one side surface in the longitudinal direction of the case 70. Supporting shafts 86 and 87 are installed at the positions at which the notches 72 and 73 are disposed in the machine casing 85. The piezoelectric motor 10 is pressed to the supporting shafts 86 and 87 by the use of coil springs 91 and 92 as an elastic member to regulate the position in the width direction. The piezoelectric motor 10 is impelled to the rotor 130 by the coil spring 93 to give a predetermined pressing force to the contact surface 131 of the rotor 130.

When the drive unit 100 having this configuration is supplied with power, the rotor 130 can be made to clockwise or counterclockwise with the rotation axis 132 as a rotation center in accordance with the driving principle (see FIGS. 3A to 3D) of the piezoelectric motor 10.

When the rotor has a ring shape (which is referred to as a ring rotor 150), the piezoelectric motor 10 can be disposed on the inner circumferential surface of the ring rotor 150. In this structure, by bringing the protrusion 28 of the piezoelectric motor 10 into contact with the inner circumferential surface 151 (corresponding to the contact surface) of the ring rotor 150, the ring rotor 150 can be made to clockwise or counterclockwise rotate with the rotation axis 152 as a rotation center.

Although not shown in the drawings, a drive unit having a driven object including a contact surface coming in contact with the protrusion 28 and a rotation axis 132 parallel to the first principal surface 20a of the piezoelectric motor 10 can be realized.

This driven object is a disk-like rotor having a rotation axis and the contact surface of the protrusion 28 comes in contact with the plane of the rotor. Therefore, this drive unit can be used, for example, when the protrusion 28 is brought into contact with the surface of a rotor such as a disk so as to rotate.

Therefore, the drive unit 100 according to this example employs the piezoelectric motor 10 with reduced vibration leakage and thus it is possible to enhance the drive energy transmission efficiency to the driven object such as the rotor 130 or the ring rotor 150 and thus to realize a drive unit 100 with high driving efficiency.

It is also possible to realize stable driving by impelling the protrusion 28 to the rotor 130 or the ring rotor 150 with a predetermined pressing force by the use of the coil spring 93. This drive unit 100 can be effectively used for a joint of a robot requiring a further decrease in weight and size than a drive unit employing a general servo motor or step motor.

### Second Example of Drive Unit

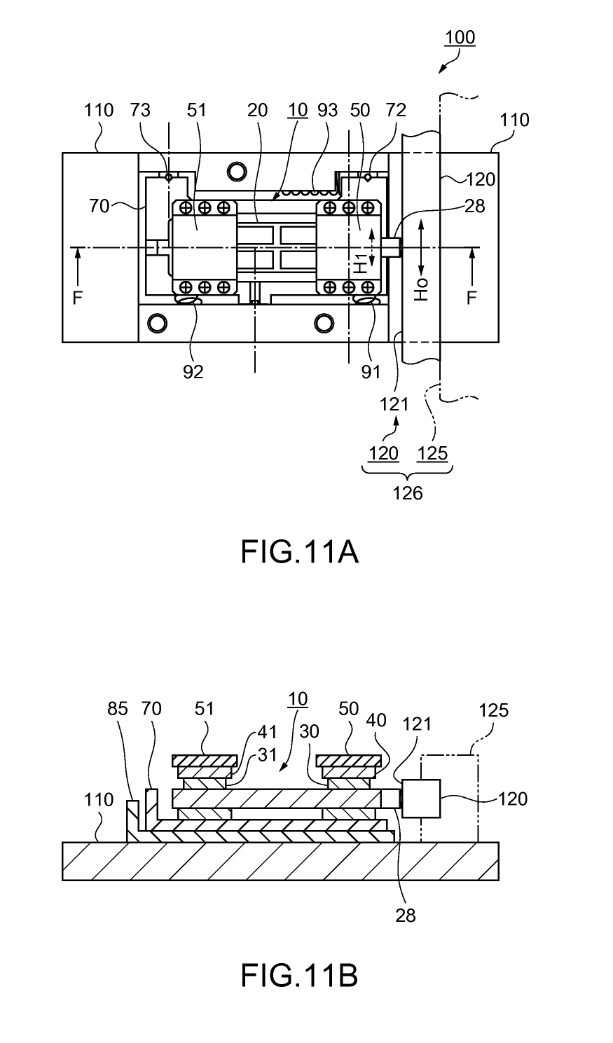

A second example of the drive unit 100 will be described below. The drive unit 100 according to this example can drive a driven object or the piezoelectric motor 10 itself to move linearly. FIGS. 11A and 11B are diagrams illustrating a second example of the drive unit 100, where FIG. 11A is a plan view and FIG. 11B is a cross-sectional view taken along line F-F of FIG. 11A. The drive unit 100 according to this example includes the piezoelectric motor 10 described in the first to fourth examples, a linear guide rail 125, a linear contact surface 121 coming in contact with the protrusion 28 of the piezoelectric motor 10, and a driven object 120 supported by the guide rail 125 and movable along the guide rail 125. The supporting structure of the piezoelectric motor 10 is the same as in the first example of the driving unit 100 (see FIGS. 10A and 10B) and thus will not be described.

In the drive unit 100 according to this example, the piezoelectric motor 10 and the guide rail 125 are mounted on the base 110 so as to be parallel to each other, and the driven object 120 is a movable object moving relative to the guide rail 125. When the drive unit 100 having this configuration is supplied with power, it can cause the driven object 120 to move forward and backward along the guide rail 125 (in the direction of arrow H₀ in the drawings) in accordance with the driving principle (see FIGS. 3A to 3D) of the piezoelectric motor 10.

When the driven object 120 shown in FIGS. 11A and 11B and the guide rail 125 are formed in a body to construct a fixed rail 126 and the piezoelectric motor 10 is used as a driven object movable along the fixed rail 126, the drive unit 100 can cause the piezoelectric motor 10 itself to move forward and backward along the fixed rail 126 (in the direction of arrow H₁ in the drawings) with the supply of power in accordance with the driving principle (see FIGS. 3A to 3D) of the piezoelectric motor 10.

Therefore, since the drive unit 100 employs the piezoelectric motor 10 with the reduced vibration leakage, it is possible to enhance the drive energy transmission efficiency to the driven object 120 and thus to achieve an increase in efficiency. When the piezoelectric motor 10 is used as a fixed object, the driven object 120 can be made to linearly move forward and backward along the guide rail 125 and is thus effectively used, for example, in a unit causing the driven object 120 to move in an X direction and a Y direction on an XY table.

When the piezoelectric motor 10 itself is used as a driven object, the piezoelectric motor 10 can be made to move forward and backward along the fixed rail 126. When a functional device is attached to the piezoelectric motor 10, the functional device can be made to move in the X direction or the Y direction on the XY table. For example, when an imaging device is used as the functional device, it is effective as an inspection apparatus. When an ink ejection head or a roll of paper cutting device is used as the functional device, it is effective as a printer or the like.

By impelling the protrusion 28 to the driven object 120 or the fixed rail with a predetermined pressing force by the use of the coil spring 93, it is possible to realize stable driving when the driven object is linearly driven.

### Robot

A robot 200 using the above-mentioned drive unit 100 will be described below.

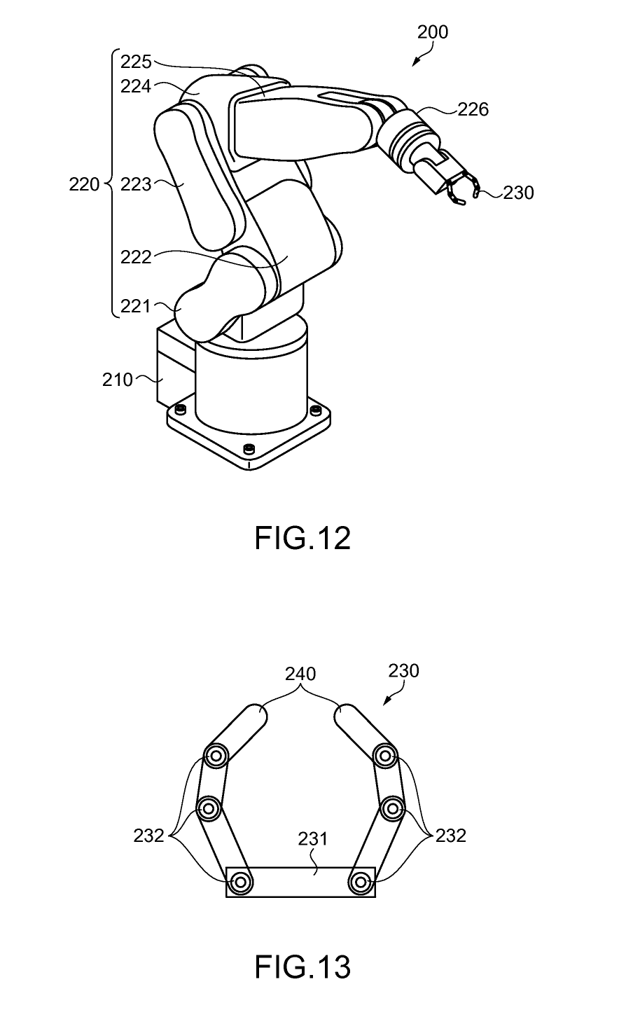

FIG. 12 is a perspective view schematically illustrating the configuration of a robot 200. The robot 200 includes a body section 210, an arm section 220, and a robot hand 230. The robot 200 shown in the drawing is classified into a so-called multi-jointed robot. The body section 210 is fixed onto, for example, a floor, a wall, a ceiling, or a movable bogie. The arm section 220 is disposed in the body section 210 so as to be rotatable or bendable. A motor (not shown) generating power for rotating the arm section 220, a controller controlling the motor, and the like are built in the body section 210.

The arm section 220 includes a first frame 221, a second frame 222, a third frame 223, a fourth frame 224, and a fifth frame 225. The first frame 221 is connected to the body section 210 via a rotating and bending mechanism so as to be rotatable and bendable. The second frame 222 is connected to the first frame 221 and the third frame 223 via a rotating and bending mechanism.

The third frame 223 is connected to the second frame 222 and the fourth frame 224 via a rotating and bending mechanism. The fourth frame 224 is connected to the third frame 223 and the fifth frame 225 via a rotating and bending mechanism. The fifth frame 225 is connected to the fourth frame 224 via a rotating and bending mechanism. The arm section 220 moves by complexly rotating or bending the frames 221 to 225 about the rotating and bending mechanisms under the control of the controller. A robot hand junction 226 is connected to the end of the fifth frame 225 of the arm section 220 opposite to the end connected to the fourth frame 224, and a robot hand 230 is attached to the robot hand junction 226. A drive unit 100 having a piezoelectric motor 10 providing a rotational motion to the robot hand 230 is built in the robot hand junction 226, whereby the robot hand 230 can grip an object (workpiece).

A drive unit 100 may be used for the rotating and bending mechanisms connecting the first to fifth frames 221 to 225, and each rotating and bending mechanism may have the drive unit 100 including the piezoelectric motor 10 and the rotor 130 as a driven object shown in FIGS. 10A and 10B so as to rotate a rotating and bending shaft (not shown). A reduction gear may be interposed between the rotor 130 and the rotating and bending shaft.

Since the robot 200 according to this embodiment employs the drive unit 100 with reduced vibration leakage and high drive force transmission efficiency, it is possible to drive the arm section 220 with high efficiency.

Since the robot hand 230 requires a light and small drive unit, the above-mentioned drive unit 100 can be effectively used. FIG. 13 is a diagram schematically illustrating the appearance of the robot hand 230. The robot hand 230 includes a finger section 240 as a small-sized arm connected to a base 231. The drive unit 100 is mounted on the junction between the base 231 and the finger section 240 and the joints 232 connecting the finger sections. The drive unit 100 includes the piezoelectric motor 10 and the rotor 130 as a driven object shown in FIGS. 10A and 10B, and can independently cause the finger sections 240 to rotationally move in desired shapes as if they were human fingers.

In this way, when the drive unit 100 is used for the joints 232 of the robot hand 230, it is possible to achieve high-efficiency driving and a decrease in weight of the robot hand 230.

The drive unit 100 can be suitably used for an orthogonal type robot in addition to the above-mentioned multi-jointed robot. Therefore, an electronic component transporting apparatus and an electronic component inspecting apparatus will be described as an application example of the orthogonal type robot.

### Electronic Component Transporting Apparatus

First, an electronic component transporting apparatus will be described, but will not be shown in the drawing. The electronic component transporting apparatus includes a gripper gripping an electronic component, an X-axis drive unit causing the gripper to move in the X axis direction, and a Y-axis drive unit causing the gripper to move in the Y axis direction perpendicular to the X-axis direction. The X-axis drive unit and the Y-axis drive unit employ the drive unit 100 illustrated in FIGS. 11A and 11B, and includes a piezoelectric motor 10 and a fixed rail 126 of which the surface coming in contact with the protrusion 28 extends linearly. The piezoelectric motor 10 can move along the fixed rail 126 with the elliptic motion of the protrusion 28. The fixed rail 126 of the X-axis drive unit extends in the Y axis direction. The fixed rail 126 of the Y-axis drive unit extends in the X axis direction. The gripper corresponds to the robot hand 230 of the robot 200 illustrated in FIGS. 12 and 13, and can employ a structure including finger sections 240 and joints 232. The joints 232 can employ the drive unit 100.

Since this electronic component transporting apparatus employs a drive unit with reduced vibration leakage and high drive force transmission efficiency, it is possible to cause the gripper to move with high efficiency. That is, it is possible to transport an electronic component with high efficiency.

### Electronic Component Inspection Apparatus

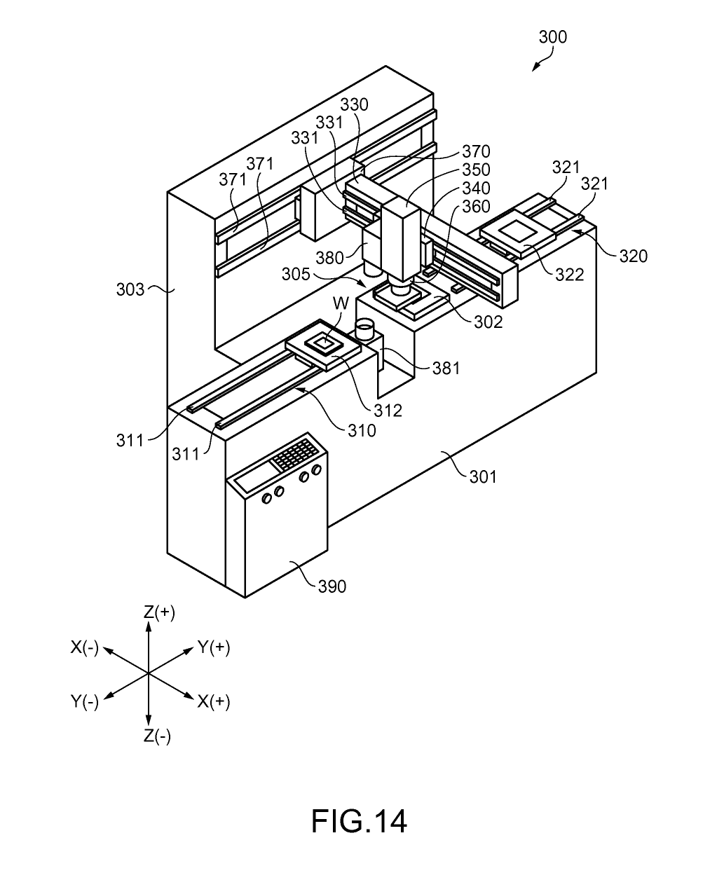

FIG. 14 is a perspective view illustrating an example of an electronic component inspecting apparatus. The electronic component inspecting apparatus 300 includes an apparatus base 301 of a rectangular parallelepiped shape. Here, the length direction of the apparatus base 301 is defined as the Y direction and the direction perpendicular to the Y direction in a horizontal plane is defined as the X direction. The direction (height direction) perpendicular to the XY plane is defined as the Z direction.

On the apparatus base 301, a workpiece feed device 310 is disposed on the left side of the drawing. On the workpiece feed device 310, a pair of guide rails 311 extending in the Y direction is disposed over all the length in the Y direction of the workpiece feed device 310. A stage 312 having a linearly-moving mechanism is disposed above the pair of guide rails 311. The linearly-moving mechanism of the stage 312 includes, for example, a linear motor movable in the Y direction along the guide rails 311. When drive signals corresponding to a predetermined number of steps are input to the linear motor, the linear motor moves forward and backward and the stage 312 moves forward or backward in the Y direction in correspondence with the same number of steps. An electronic component W is placed on the stage 312.

In the apparatus base 301, a second imaging unit 381 is disposed on the +Y side of the workpiece feed device 310. The second imaging unit 381 includes an electric circuit board on which a charge coupled device (CCD) converting received light into electric signals or the like is mounted, an objective lens including a zoom mechanism, an epi-illumination device, and an automatic focusing device. When the electronic component W is located at a position facing the second imaging unit 381, the second imaging unit 381 can image the electronic component W. The second imaging unit 381 can capture an in-focus image by capturing an image after applying light to the electronic component W and focusing the electronic component W.

In the apparatus base 301, an inspection table 302 is disposed on the +Y side of the second imaging unit 381. The inspection table 302 is a jig used to transmit and receive electric signals when inspecting the electronic component W.

On the apparatus base 301, a workpiece removing device 320 is disposed on the +Y side of the inspection table 302. A pair of guide rails 321 extending in the Y direction is disposed on the top surface of the workpiece removing device 320. A stage 322 having a linearly-moving mechanism is mounted on the guide rail 321. The linearly-moving mechanism of the stage 322 can employ the same mechanism as the linearly-moving mechanism of the stage 312. The stage 322 moves forward or backward along the guide rails 321. An electronic component W is placed on the stage 322.

A support table 303 of a substantially rectangular parallelepiped shape is disposed on −X side of the apparatus base 301. The support table 303 is higher in +Z direction than the apparatus base 301. In the support table 303, a pair of guide rails 371 extending in the Y direction is disposed on the plane facing the +X side, and a Y stage 370 having a linearly-moving mechanism moving along the guide rails 371 is mounted thereon.

The guide rails 371 correspond to the fixed rail 126 (see FIGS. 11A and 11B) in the above-mentioned drive unit 100 and movably support the Y stage 370. The Y stage 370 includes a drive unit 100 including a piezoelectric motor 10. The plane of the guide rails 371 facing the Y stage 370 is a contact surface 121 with which the protrusion 28 of the piezoelectric motor 10 comes in contact (see FIGS. 11A and 11B). By activating the piezoelectric motor 10, the Y stage 370 moves forward or backward in the Y direction along the guide rails 371.

On the plane of the Y stage 370 facing the +X side, an arm 330 extends in the +X direction. A pair of guide rails 331 extending in the +X direction is disposed on the plane of the arm 330 facing the −Y side. An X stage 340 having a linearly-moving mechanism moving along the guide rails 331 is mounted thereon.

The guide rails 331 correspond to the fixed rail 126 (see FIGS. 11A and 11B) in the above-mentioned drive unit 100 and movably supports the X stage 340. The X stage 340 includes the above-mentioned drive unit 100 including the piezoelectric motor 10. A partial plane of the guide rails 331 corresponds to the contact surface 121 with which the protrusion 28 of the piezoelectric motor 10 comes in contact (see FIGS. 11A and 11B). By activating the piezoelectric motor 10, the X stage 340 moves forward or backward in the X direction along the guide rails 331.

A first imaging unit 380 as an imaging unit and a Z moving device 350 are disposed on the X stage 340. The first imaging unit 380 has the same structure and function as the second imaging unit 381. The Z moving device 350 includes a linearly-moving mechanism therein and the linearly-moving mechanism lifts up and down a Z stage (not shown). A rotating device 360 is disposed in the Z stage. The Z moving device 350 can lift up and down the rotating device 360 in the Z direction. The linearly-moving mechanism of the Z moving device 350 may include the above-mentioned drive unit 100, similarly to the Y stage 370 moving along the guide rails 371 and the X stage 340 moving along the guide rails 331.

A control device 390 as a controller is disposed in the apparatus base 301. The control device 390 has a function of controlling the overall operations of the electronic component inspecting apparatus 300. The control device 390 also has a function of inspecting an electronic component W. Although not shown in the drawing, the control device 390 includes an input unit and an output unit. The input unit includes a keyboard or an input connector, and is a device for inputting an operator's instruction in addition to signals and data. The output unit includes an output connector outputting data to a display device or an external device, and outputs signals or data to another device.

In the above-mentioned configuration, the inspection unit 305 performs a process of re-feeding an electronic component W as an inspection target, an imaging process, and an electric characteristic measuring process, and the like. The electronic component W is transported from the workpiece feed device 310 to the inspection table 302 and the workpiece removing device 320 through the use of the guide rails 371, the Y stage 370, the guide rails 331, the X stage 340, the Z moving device 350, the rotating device 360, and the like.

The electronic component W to be inspected by the electronic component inspecting apparatus 300 is generally placed under clean circumstances, that is, under dust-proof circumstances. Before being placed on the inspection table 302, the position of the electronic component W is processed on the basis of the image of the electronic component W obtained by the first imaging unit 380 and the second imaging unit 381 and is accurately regulated relative to a predetermined position of the inspection table 302.

Since an electronic component W is often small-sized, precise, and multi-functioned, so-called total inspection is generally performed thereon. Therefore, since the number of electronic components W to be inspected is very large, it is necessary to shorten the inspection period of an electronic component W. Particularly, it is necessary to shorten the transport time of an electronic component W in the inspection period. Therefore, in the Y stage 370, the X stage 340, and the Z moving device 350 including the drive unit 100 using the above-mentioned piezoelectric motor 10, it is possible to control the acceleration time up to a predetermined moving speed and a deceleration time up to a stop to be shorter and thus to realize an electronic component inspecting apparatus 300 with a reduced inspection period.

Representative examples of the electronic component W include a “semiconductor device”, a “display device such as CLD or OLED”, a “crystal device”, a “variety of sensors”, an “inkjet head”, and a “variety of MEMS devices”.

The above-mentioned drive unit 100 having the piezoelectric motor 10 is not limited to the electronic component inspecting apparatus 300, but can be applied to devices having a function of causing functional elements to move linearly or to move rotationally. Therefore, a printer will be described as an example of such devices.

### Printer

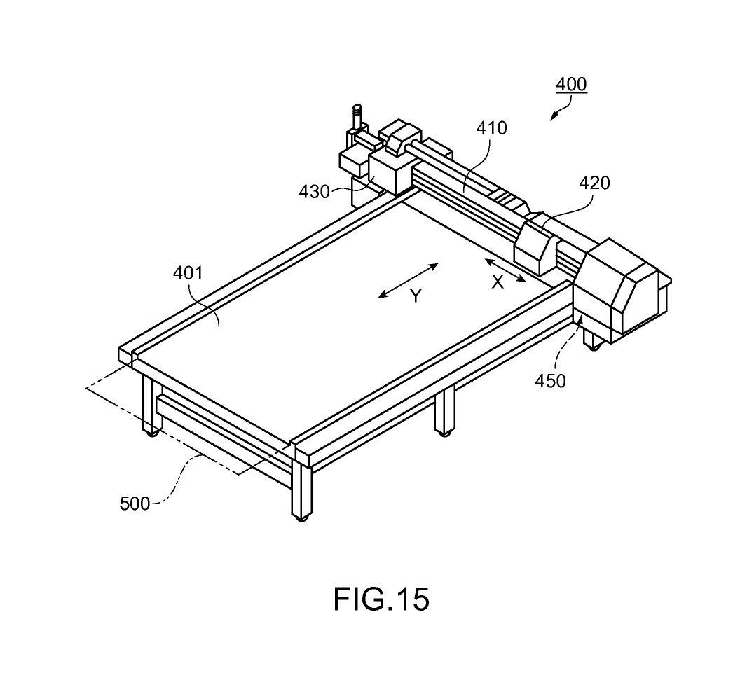

FIG. 15 is a perspective view schematically illustrating a printer 400. The printer 400 includes a transport table 401 over which a sheet-like recording medium is transported, a guide rail 410 disposed at one end of the transport table 401 and extending in the width direction (X direction) of the transport table 401, an ejection head 420 capable of moving forward and backward along the guide rail 410 and ejecting liquid droplets, a cutting device 430, and a control device 450 controlling the entire printer.

In the printer 400 according to this example, the recording medium is a roll of paper 500, and a transport device (not shown) causing the roll of paper 500 to reciprocate in the Y direction is provided. The liquid droplets include ink or liquid including metal powder. Therefore, in this example, the ejection head 420 can be replaced with an ink ejection head 420, and can reciprocate in the direction (the X direction) perpendicular to the transport direction (the Y direction) of the roll of paper 500. The ink ejection head 420 can employ various known techniques and thus will not be described.

The cutting device 430 includes a drive unit 100 allowing the cutting device to moving forward and backward along the guide rail 410 and a cutter cutting the roll of paper 500 at a predetermined position.

The cutting device 430 will be described below.

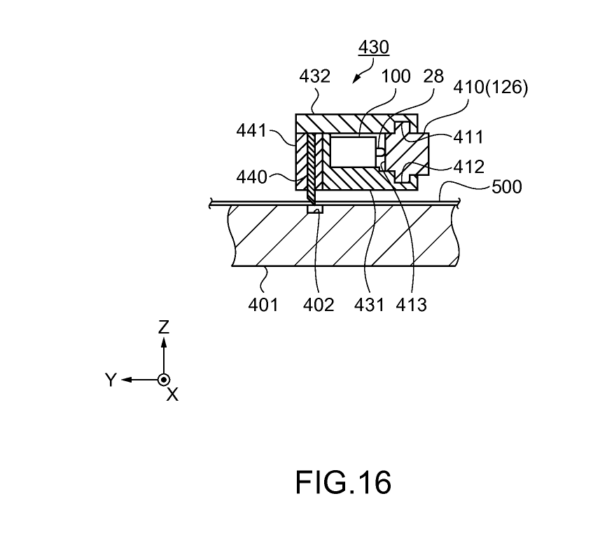

FIG. 16 is a cross-sectional view illustrating an example of the cutting device 430. The cutting device 430 includes a drive unit 100 and a cutter 440 mounted on the drive unit 100. The drive unit 100 employs the structure shown in FIGS. 11A and 11B. The guide rail 410 corresponds to the fixed rail 126 as a fixed object and the drive unit 100 is a driven object having the piezoelectric motor 10.

The piezoelectric motor 10 is disposed in a space formed by a lower machine casing 431 and an upper machine casing 432, and is fixed to the lower machine casing 431. The cutter 440 fixed to a cutter frame 441 is mounted on the lower machine casing 431. The cutting edge of the cutter 440 protrudes up to a position at which it can cut the roll of paper 500. The cutting device 430 is supported by the guide rail 410 by fitting grooves formed in the lower machine casing 431 and the upper machine casing 432 to guide portions 411 and 412 of the guide rail 410 formed in the vertical direction in the drawing. The protrusion 28 of the piezoelectric motor 10 comes in contact with the contact surface 413 of the guide rail 410 and the piezoelectric motor 10 itself moves forward and backward along the guide rail 410 with the elliptic motion of the protrusion 28.

At this time, the roll of paper 500 is cut by the cutter 440. The cutter 440 is located at a position departing from the width direction of the roll of paper 500 when the ink ejection head 420 ejects the ink, and moves in the X direction and cuts the roll of paper 500 at a predetermined position when the ejection of ink is ended or when the ejection of ink is not performed. By forming a groove 402 or disposing a material (such as resin) having lower hardness than that of the cutter 440 in the moving locus range of the cutter 440 on the top surface of the transport table 401 coming in contact with the roll of paper 500, it is possible to extend the lifetime of the cutter.

A structure in which the cutter 440 may be mounted on a Z driving mechanism capable of reciprocating in the Z direction and the drive unit 100 is used as the Z driving mechanism may be employed.

The drive unit 100 used for the cutting device 430 may be used to drive the ink ejection head 420.

In the printer 400 according to this example, the ink ejection head 420 and the cutting device 430 are supported by the common guide rail 410, but may be supported by dedicated guide rails, respectively.

In this way, the printer 400 includes the cutting device 430, and the cutting device 430 includes the drive unit 100 having the structure described with reference to FIGS. 11A and 11B. Since the drive unit 100 includes the piezoelectric motor 10 which can be driven with high efficiency as described above, it is possible to realize a printer 400 capable of decreasing in size and weight and having a small driving load.

The entire disclosure of Japanese Patent Application No. 2011-267225, filed Dec. 6, 2011 is expressly incorporated by reference herein.

What is claimed is:

1. A piezoelectric motor comprising:
a piezoelectric element that vibrates by excitation of a bending vibration mode or vibrates by excitation of both the bending vibration mode and a longitudinal vibration mode;
an upper support member that comes in surface contact with supporting portions distributed toward four corners of a first principal surface of the piezoelectric element;
a pressing member that comes in surface contact with the surface of the upper support member facing the first principal surface;
a lower support member that is disposed at a position plane-symmetric with respect to the upper support member with the piezoelectric element interposed therebetween and that comes in surface contact with the piezoelectric element;
a machine casing member that comes in surface contact with the surface of the lower support member opposite to the contact surface thereof with the piezoelectric element; and
an elastic member that presses a stacked body in which the machine casing member, the lower support member, the piezoelectric element, the upper support member, and the pressing member are sequentially stacked at positions of the supporting portions.

2. The piezoelectric motor according to claim 1, wherein the supporting portions are arranged in a range around a line passing through nodes of secondary bending vibration of the piezoelectric element and being perpendicular to the longitudinal vibration of the piezoelectric element.

3. The piezoelectric motor according to claim 1, wherein excitation electrodes are formed at positions corresponding to the supporting portions on the first principal surface of the piezoelectric element,
wherein a common electrode is formed on a second principal surface of the piezoelectric element opposite to the first principal surface,
wherein unevenness is formed on a contact surface of the upper support member with the excitation electrodes, and
wherein unevenness is formed on a contact surface of the lower support member with the common electrode.

4. The piezoelectric motor according to claim 1, wherein excitation electrodes are formed at positions corresponding to the supporting portions on the first principal surface of the piezoelectric element,
wherein a common electrode is formed on a second principal surface of the piezoelectric element opposite to the first principal surface,
wherein unevenness is formed on a contact surface of the excitation electrodes with the upper support member, and
wherein unevenness is formed on a contact surface of the common electrode with the lower support member.

5. The piezoelectric motor according to claim 1, wherein excitation electrodes are formed at positions corresponding to the supporting portions on the first principal surface of the piezoelectric element,
wherein a common electrode is formed on a second principal surface of the piezoelectric element opposite to the first principal surface,
wherein unevenness is formed on both contact surfaces of the upper support member and the excitation electrodes, and
wherein unevenness is formed on both contact surfaces of the lower support member and the common electrode.

6. The piezoelectric motor according to claim 5, wherein unevenness is formed on one or both of the contact surfaces of the upper support member and the pressing member and on one or both of the contact surfaces of the lower support member and the machine casing member.

7. A drive unit comprising:
the piezoelectric motor according to claim 1;
a driven object that is driven by an elliptic motion of the supporting portions; and
an elastic member that impels the supporting portions to the driven object.

8. A drive unit comprising:
the piezoelectric motor according to claim 2;
a driven object that is driven by an elliptic motion of the supporting portions; and
an elastic member that impels the supporting portions to the driven object.

9. A drive unit comprising:
the piezoelectric motor according to claim 3;
a driven object that is driven by an elliptic motion of the supporting portions; and
an elastic member that impels the supporting portions to the driven object.

10. The drive unit according to claim 7, wherein the driven object includes a contact surface coming in contact with the supporting portions and a rotation axis perpendicular to the first principal surface or parallel to the first principal surface.

11. The drive unit according to claim 7, further comprising a straight guide rail that supports the driven object,
wherein the driven object includes a contact surface coming in contact with the supporting portions and is supported to be movable along the guide rail.

12. The drive unit according to claim 7, further comprising:
a fixed rail of which a surface in contact with the supporting portions extends straightly; and
an elastic member that impels the supporting portions to the fixed rail,
wherein the piezoelectric motor is movable along the fixed rail by the elliptic motion of the supporting portions.

13. A robot comprising:
an arm;
a joint that is linked to the arm; and
the drive unit according to claim 8 that is disposed in the joint.

14. An electronic component transporting apparatus comprising:
a gripper that grips an electronic component;
an X-axis drive unit that causes the gripper to move in an X-axis direction; and
a Y-axis drive unit that causes the gripper to move in a Y-axis direction perpendicular to the X-axis direction,
wherein the X-axis drive unit and the Y-axis drive unit employ the drive unit according to claim 10.

15. An electronic component inspecting apparatus comprising:
an inspection unit that inspects an inspected object;
a first drive unit that causes the inspection unit to move in an X-axis direction; and
a second drive unit that causes the inspection unit to move in a Y-axis direction perpendicular to the X-axis direction,
wherein the first drive unit and the second drive unit employ the drive unit according to claim 10.

16. A printer comprising:
a transport mechanism that transports a recording medium;
an ejection head that ejects droplets to the recording medium; and
the drive unit according to claim 10 that is movable in a direction perpendicular to the transport direction of the recording medium.

17. A piezoelectric motor comprising:
a piezoelectric element;
a first support member and a second support member that are disposed on one surface of the piezoelectric element and that support the piezoelectric element;
a third support member and a fourth support member that are disposed on the other surface opposite to the one surface of the piezoelectric element and that support the piezoelectric element;
a pressing member that presses the first support member and the second support member from the one surface;
a machine casing member that presses the third support member and the fourth support member from the other surface; and
an elastic member that comes in contact with the pressing member and that presses the pressing member toward the piezoelectric element,
wherein the third support member is disposed to face the first support member with the piezoelectric element interposed therebetween,
wherein the fourth support member is disposed to face the second support member with the piezoelectric element interposed therebetween, and
wherein the one surface and the other surface are parallel to the bending vibration direction of the piezoelectric element.

18. A robot hand comprising:
a finger;
a joint that is linked to the finger;
a piezoelectric element that is disposed in the joint;
a first support member and a second support member that are disposed on one surface of the piezoelectric element and that support the piezoelectric element;
a third support member and a fourth support member that are disposed on the other surface opposite to the one surface of the piezoelectric element and that support the piezoelectric element;
a pressing member that presses the first support member and the second support member from the one surface;
a machine casing member that presses the third support member and the fourth support member from the other surface; and
an elastic member that comes in contact with the pressing member and that presses the pressing member toward the piezoelectric element,
wherein the third support member is disposed to face the first support member with the piezoelectric element interposed therebetween,
wherein the fourth support member is disposed to face the second support member with the piezoelectric element interposed therebetween, and
wherein the one surface and the other surface are parallel to the bending vibration direction of the piezoelectric element.

19. A robot comprising the robot hand according to claim 16.

20. An electronic component transporting apparatus comprising the piezoelectric motor according to claim 15.
